(19) United States
(12) Patent Application Publication
(10) Pub. No.: US 2023/0084379 A1
(43) Pub. Date: Mar. 16, 2023

(54) LOCAL BRIDGE-LAST ARCHITECTURE FOR HETEROGENEOUS INTEGRATION APPLICATIONS

(71) Applicants: Gang Duan, Chandler, AZ (US); Srinivas Venkata Ramanuja Pietambaram, Chandler, AZ (US); Aleksandar Aleksov, Chandler, AZ (US); Tarek Ibrahim, Mesa, AZ (US)

(72) Inventors: Gang Duan, Chandler, AZ (US); Srinivas Venkata Ramanuja Pietambaram, Chandler, AZ (US); Aleksandar Aleksov, Chandler, AZ (US); Tarek Ibrahim, Mesa, AZ (US)

(21) Appl. No.: 17/472,081

(22) Filed: Sep. 10, 2021

(51) Int. Cl. H01L 23/538; H01L 25/065; H01L 23/00; H01L 23/13; H01L 23/498; H01L 21/48; H01L 21/56; H01L 21/683; H01L 25/00

(52) U.S. Cl. CPC H01L 23/5381; H01L 25/0655; H01L 24/16; H01L 23/13; H01L 23/49827; H01L 21/4853; H01L 21/486; H01L 21/563; H01L 21/565; H01L 21/6835; H01L 25/50; H01L 2224/16227; H01L 2221/68372

(57) ABSTRACT

Disclosed herein are local bridge-last architectures for heterogeneous integration applications and methods for manufacturing the same. The local bridge-last architectures may include a substrate, a first die, a second die, and a material. The substrate may define a cavity. The first and second dies may be connected to the substrate. The material may be attached to the substrate. The material may include a first portion and a second portion. The first portion of the material may be located proximate the first bump and the second portion of the material may be located proximate the second bump.

### FIELD OF THE DISCLOSURE

The present subject matter relates to microelectronics packages. More specifically, the present disclosure relates to bridge architecture for heterogeneous die integration in microelectronics package applications.

### BACKGROUND

Considerable engineering effort has been made to define the fine and coarse bump profiles that may support die attachment and via connection processing. Dies may have focused bump height control and solder volume, which may enable dual pitch and profile configurations. The mixed bump pitch may introduce significant technical challenges, which are overcome using the systems and methods disclosed herein.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows a microelectronics package in accordance with at least one example of this disclosure.

FIGS. 2A and 2B each shows a cross-section of a section of a microelectronics package in accordance with at least one example of this disclosure.

FIGS. 3A, 3B, 3C, and 3D each shows a cross-section of a section of a microelectronics package in accordance with at least one example of this disclosure.

FIGS. 4A and 4B show a process flow for forming a microelectronics packages in accordance with at least one example of this disclosure.

FIGS. 5A, 5B, and 5C show a process flow for forming a microelectronics packages in accordance with at least one example of this disclosure.

FIG. 6 shows system level diagram in accordance with at least one example of this disclosure.

### DETAILED DESCRIPTION

As demands for high performance computing (HPC) continue to rise, heterogeneous integration has become an important performance enabler. The focus to enable heterogeneous integration scaling may be to push interconnect density with increased bandwidth and improved power efficiency. Using the systems and methods disclosed herein, many different advanced packaging architectures may be deployed to increase planar and 3D input/output (I/O) wire per area density for higher data bandwidth requirements, and to enable more effective die disaggregation per heterogeneous integration to shorten the time to market.

As disclosed herein, embedded multi-die interconnect bridge (EMIB) technology may be an advanced, cost-effective approach to in-package high density interconnects of heterogeneous chips, providing high density I/O, and controlled electrical interconnect paths between multiple dice in a package. The systems and methods disclosed herein may use local silicon bridges to host ultrafine line and space structures for die-to-die interconnect communications and open avenues for heterogeneous chip integration applications.

In addition, the EMIB technology disclosed here may be used to connect vertically stacked 3D silicon (Si) elements, sometimes referred to as co-EMIB. Co-EMIB packaging technology disclosed herein may allow for the interconnection of two or more elements, such as dies, tiles, etc., for even more computing performance and capability. Using the systems and methods disclosed herein, product designers may connect analog, memory, and other tiles with high bandwidth and at low power. Combining EMIB and interposer technologies may help to overcome the manufacturing limitations in large-die, high-performance applications.

Beyond EMIB, interposers, and Co-EMIB, an omni-directional interconnect (ODI) packaging technology may be fabricated and implemented using local silicon interconnects for die-to-die communications to enable scaling enabler for heterogeneous integration applications.

As disclosed herein, silicon bridges, interposers, EMIBs, etc., generally referred to herein as a bridge) may be used to allow electrical communications between one or more dies. The bridge may be located within a cavity defined by a substrate. During the manufacturing process, the cavity may be formed by laser drilling, etching, etc. To limit a depth of the cavity, a material may be attached to or embedded within the substrate. During cavity formation, the material may be a stopping material that may limit the effectiveness of an etching process or otherwise absorb, reflect, etc. a laser drill to define the depth of the cavity. Once the cavity is formed the bridge may be placed into the cavity and connected to the dies.

The systems and methods disclosed herein overcome the technical challenges associated with mixed bump pitch by enabling a silicon bridge last architecture to address the mixed bump pitch assembly process challenges. The systems and methods disclosed herein apply in at least organic substrates/interposers, glass cored substrates/interposers, and ODI-like molded patches/interposers, etc. The systems and methods disclosed herein also allow for more interconnect options, which may allow for mixed hybrid bonding to enable even more aggressive pitch scaling.

The above discussion is intended to provide an overview of subject matter of the present patent application. It is not intended to provide an exclusive or exhaustive explanation. The description below is included to provide further information.

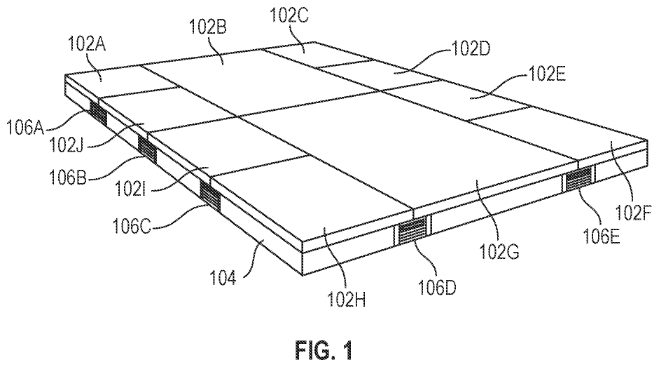

Turning now to the figures, FIG. 1 shows a microelectronics package 100 in accordance with at least one example of this disclosure. Microelectronics package 100 may include dies 102 (labeled individually as die 102A, 102B, . . . 102J) connected to a substrate 104. Dies 102 may be any type of dies, such as, but not limited to, logic dies, high bandwidth memory dies, graphical processing unit dies, transmitter/receiver/transceiver dies, etc. Substrate 104 may define one or more cavities for receiving one or more bridges 106 (labeled individually as bridge 106A, 106B, . . . 106E). As disclosed herein, bridges 106 may be silicon bridges, interposers, EMIBs, etc. While FIG. 1 shows a two-dimensional integration, a three-dimensional integration is consistent with examples of this disclosure.

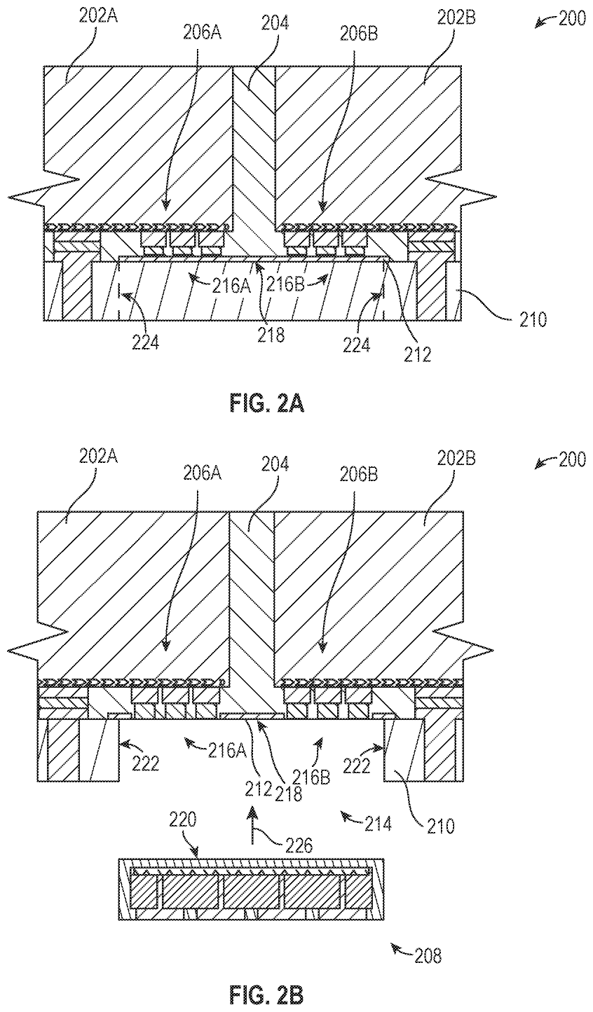

FIGS. 2A and 2B each shows a cross-section of a section of a microelectronics package 200 in accordance with at least one example of this disclosure. For example, FIGS. 2A and 2B may represent a cross-section of microelectronics package 100 along any of bridges 106. Microelectronics package 200 may include a first die 202A and a second die 202B (collectively dies 202). Dies 202 may be embedded within a mold 204 having a first set of vias 206A and a second set of vias 206B (collectively vias 206). Vias 206 may connect dies 202 to a bridge 208. Bridge 208 may be embedded at least partially within a substrate 210, but is shown separated from vias 206 and dies 202 for clarity.

As disclosed herein, a material 212 may be connected to substrate 210 and bridge 208. Material 212 may allow for a cavity 214 to be formed in substrate 210 in which bridge 208 rests to be formed by a laser drilling or etching process as disclosed herein. For example, material 212 may be located proximate a first bump 216A of first die 202A and a second bump 216B of second die 202B and have a surface 218 that has a surface area that is greater than a surface area of a surface 220 of bridge 208. Thus, when forming cavity 214 in substrate 210 stopping surface 212 may act as a stop to limit a depth of cavity 214 as disclosed herein, while the surfaces 222 can define a boundary for cavity 214. Thus, a portion of surface 218 of material 212 may have a projection (shown by lines 224) that defines the boundary of cavity 214. As disclosed herein and shown in FIG. 2B, once cavity 214 is formed, portions of material 212 may be etched and/or otherwise removed to allow for bridge 208 to be installed at least partially within cavity 214 as indicated by arrow 226.

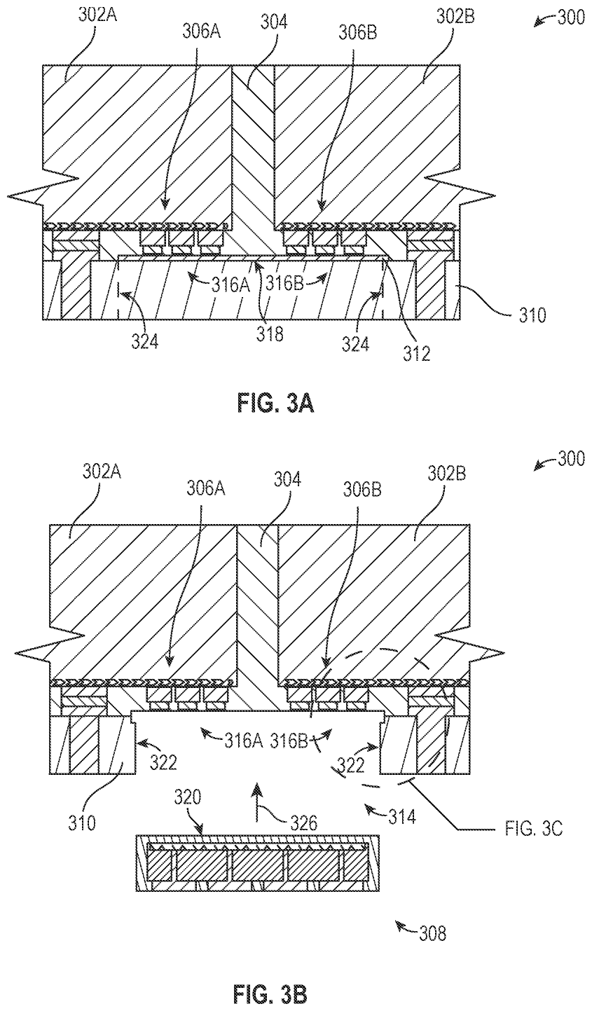

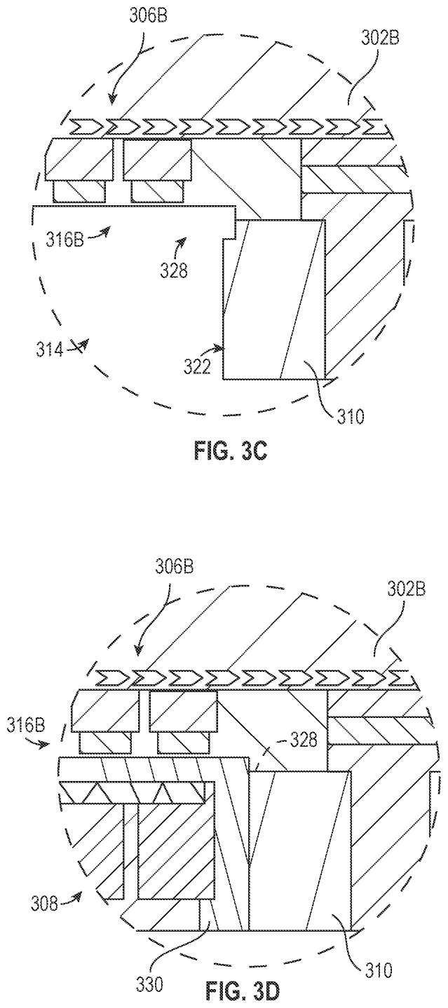

FIGS. 3A and 3B each shows a cross-section of a section of a microelectronics package 300 in accordance with at least one example of this disclosure. For example, FIGS. 3A and 3B may represent a cross-section of microelectronics package 100 along any of bridges 106. Microelectronics package 300 may include a first die 302A and a second die 302B (collectively dies 302). Dies 302 may be embedded within a mold 304 having a first set of vias 306A and a second set of vias 306B (collectively vias 306). Vias 306 may connect dies 302 to a bridge 308. Bridge 308 may be embedded at least partially within a substrate 310, but is shown separated from vias 306 and dies 302 for clarity.

As disclosed herein, a material 312 may be connected to substrate 310. Material 312 may allow for a cavity 314 in which bridge 308 rests to be formed in substrate 310 by a laser drilling or etching process as disclosed herein. For example, material 312 may be located proximate a first bump 316A of first die 302A and a second bump 316B of second die 302B and have a surface 318 that has a surface area that is greater than a surface area of a surface 320 of bridge 308. Thus, when forming cavity 314 in substrate 310 stopping surface 312 may act as a stop to limit a depth of cavity 314 as disclosed herein, while the surfaces 322 can define a boundary for cavity 314. Thus, a portion of surface 318 of material 312 may have a projection (shown by lines 324) that defines the boundary of cavity 314. As disclosed herein and shown in FIG. 3B, once cavity 314 is formed, material 312 may be etch and/or otherwise removed to allow for bridge 308 to be installed at least partially within cavity 314 as indicated by arrow 326.

As shown in FIG. 3C, when material 312 is removed a notch 328 may be formed in substrate 310. As shown in FIG. 3D, when bridge 308 is installed, notch 328 may be filled with the same material used to form substrate 310 and mold 304. While FIG. 3D shows notch filled with the same materials as substrate 310 and mold 304, any number of materials may be used to fill notch 328. For example, bridge 328 may include a molding 330 that is a different material than substrate 310 and a material having a coefficient of thermal expansion similar to either substrate 310, mold 304, mold, 330, or some combination thereof, may be used to fill notch 328.

While FIGS. 2A-3D each show a single bridge, a single material, and two dies, embodiments contemplated herein may include any number of materials, bridges, and dies. For example, A third die may be connected to the substrate. The third die may comprise a third bump. A second material may be attached to the substrate and a first portion of the second material may be located proximate the third bump. A second portion of the second material located proximate the first bump or the second bump. The second material may be used to etch and/or drill a cavity in the substrate as disclosed herein so that a second bridge may be installed to connect the third die to one or both of the dies.

In addition to multiple materials (i.e., plates of materials), material may be as single plate of material. Thus, a third die may be connected to the substrate. The third bump of the third die may be located proximate a different section of the material to allow for a second cavity to be formed in the substrate. The second cavity may be used to connect the third die to one or both of the dies.

As disclosed herein, non-limiting examples of the material may include an etch material and/or a laser material. Specific examples of the material may include, but are not limited to, a copper plate, a titanium plate, an alloy of copper and titanium, silicon dioxide, silicon nitride, etc.

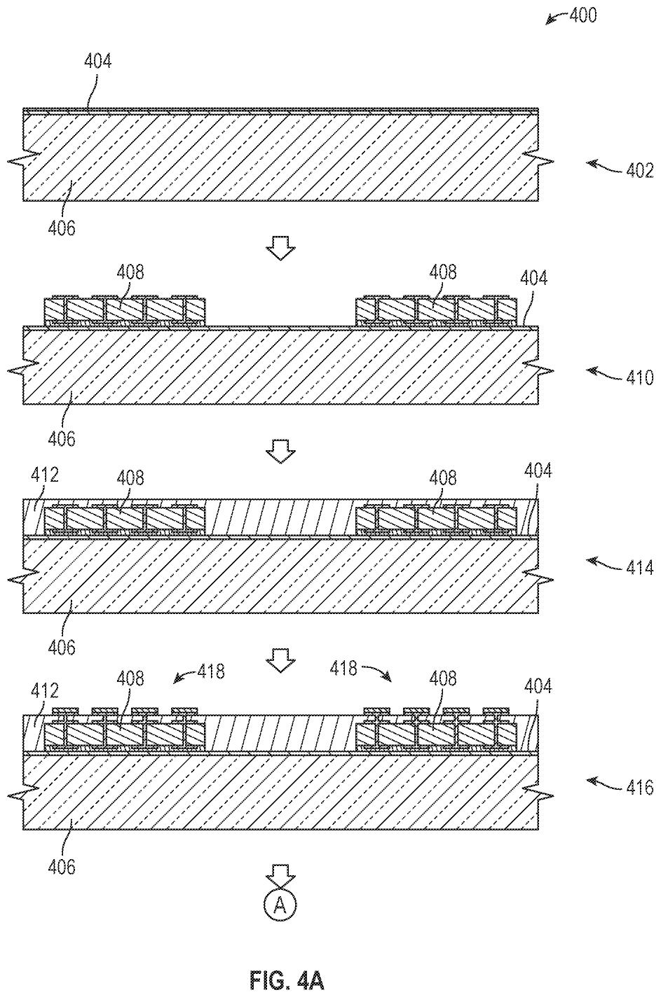

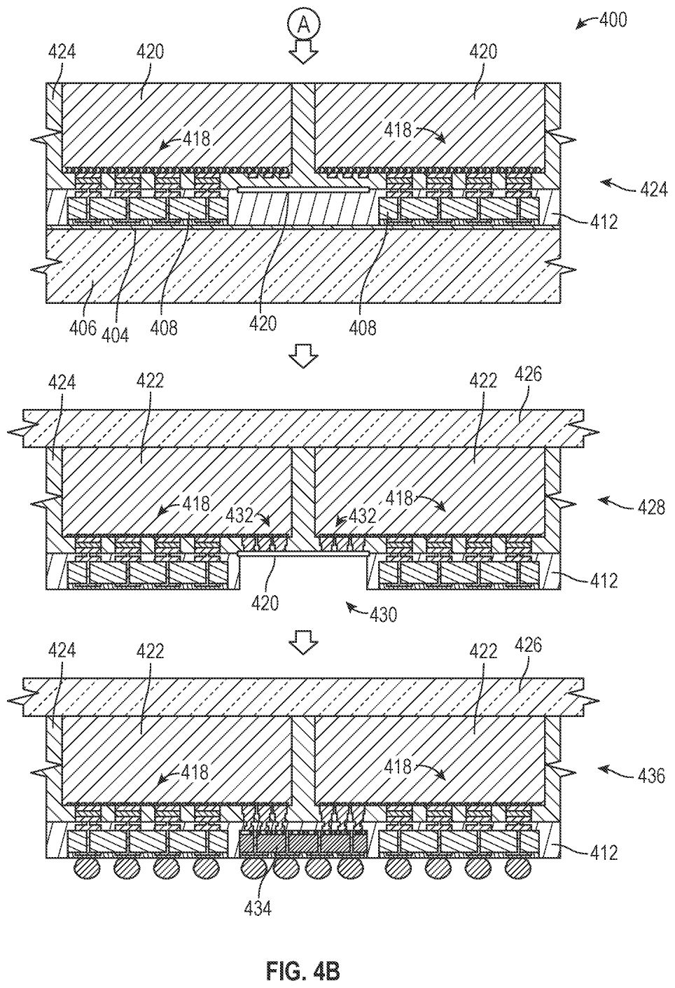

FIGS. 4A and 4B show a process flow 400 for forming microelectronics packages, such as microelectronics package 100, in accordance with at least one example of this disclosure. Process flow 400 may begin at stage 402 where a release layer 404 may be applied to a carrier 406. Carrier 406 may be a glass carrier. Carrier 406 may also be silicon.

After application of release layer 404, one or more interposers 408 can be positioned on carrier 406 (410). Interposes 408 may be glass core interposers. Glass core interposes may be used to provide extra strength and stability of the microelectronics package formed using process flow 400 as disclosed herein. At a wafer-level process, silicon wafers may be used as carriers as disclosed herein. In this case instead of glass interposer die-lets or a glass wafer-level-interposer with openings for the ODI/bridge die, a thinned silicon wafer may be placed on top of the silicon carrier as the interposer.

After interposes 408 are positioned, a substrate 412 may be formed (414) on carrier 406. For example, Ajinomoto Build-up Film (ABF) or solder resist (SR) lamination may be used to form substrate 412. Mold and chemical mechanical polishing (CMP) or other planarizing operations may be applied as needed.

At stage 416 SIB micro-bumping may be attached to interposes 408. For example, copper and solder plating 418 may be deposited or otherwise positioned on substrate 412. As needed, vias may be formed in substrate 412 to allow copper and solder plating 418 to form an electrical connection with interposes 408. Once copper and solder plating 418 have been deposited, a material 420 may be attached or otherwise deposited to substrate 412 (424). As disclosed herein, attaching material 420 to substrate 412 may include plating an etch material to substrate 412. Still consistent with embodiments disclosed herein, attaching material 420 to substrate 412 may include plating a laser material to substrate 412. Plating the etch material and/or the laser material may be performed with or without solder.

One or more dies 422 may be attached and a mold 424 formed around dies 422 (424). Mold 424 may be ground as needed to be even with a top surface of dies 422 after an underfill process is used to form mold 424. For example, an underfilling process may be used to surround a portion of die 422. Mold 424 may contact substrate 412 and dies 422. Once mold 424 cures, a grinding process may be used to remove and flash or other portions of mold 424 as needed.

After attaching dies 422, a second carrier 426 may be attached to dies 422 (428). After attaching second carrier 426, a cavity 430 may be formed in substrate 412. For example, cavity 430 may be formed using a laser drilling process. During the laser drilling process, material 420 may limit the depth of cavity 430 by reflecting, absorbing, or a combination there the laser used to form cavity 430. Forming cavity 430 may also include etching or otherwise forming holes within material 420 to allow for an electrical connection between bumps 432 and a bridge 434. Cavity 430 may also be formed via plasma dry etching process such as reactive ion etching (RIE).

Once cavity 430 is formed a bridge 434 may be installed in cavity 430 (436). Installing of bridge 434 may include electrically connecting bridge 434 to dies 422 via bumps 432 as disclosed herein at least with respect to FIGS. 2A-3D. After installing bridge 434, solder bumps 438 may be applied and second carrier 426 may be removed.

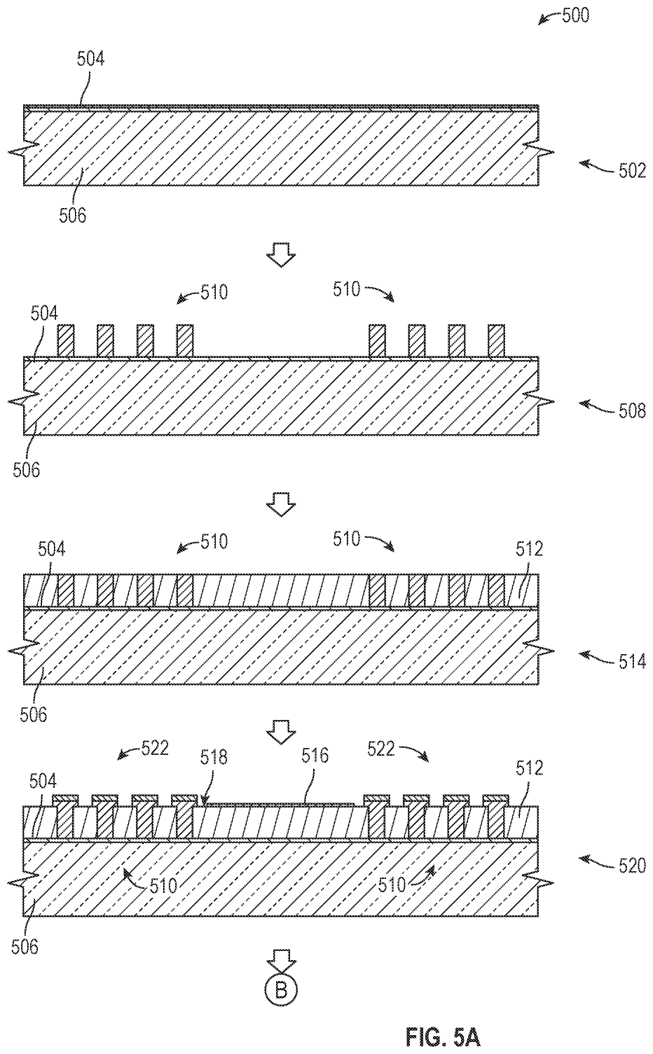

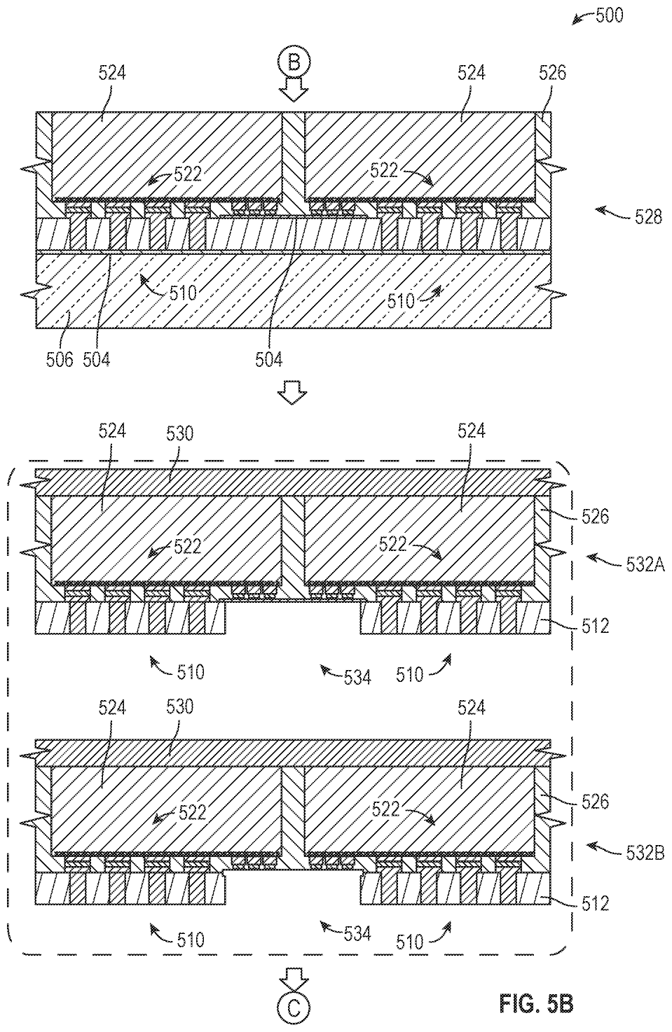

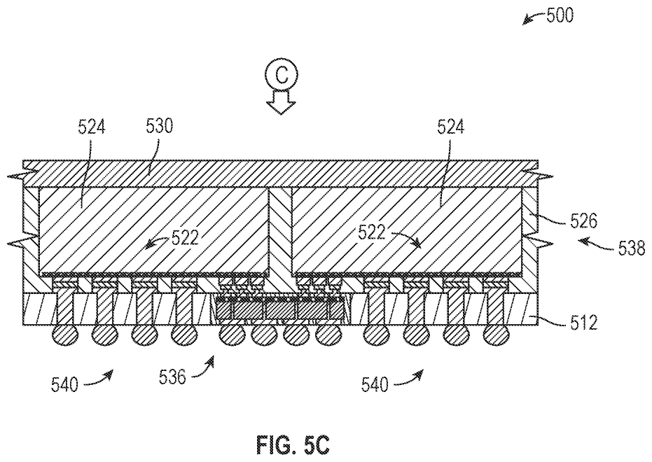

FIGS. 5A, 5B, and 5C show a process flow 500 for forming microelectronics packages, such as microelectronics package 100, in accordance with at least one example of this disclosure. Process flow 500 may begin at stage 502 where a release layer 504 may be applied to a carrier 506. Carrier 506 may be a glass carrier or a silicon carrier as disclosed herein.

As shown in stage 508, pillars 510 may be formed. Pillars 510 may be interconnect pillars. Pillars 510 may be formed via additive and/or semi-additive processes. Once pillars 510 are formed, a substrate 512 may be formed around pillars 510 (514). ABF or SR lamination may be used to form substrate 512 as disclosed herein.

After substrate 512 is formed, a material 516 may be formed on a surface 518 of substrate 512 (520). As disclosed herein, attaching material 516 to substrate 512 may include plating an etch material, such as titanium, to substrate 512. Still consistent with embodiments disclosed herein, attaching material 516 to substrate 512 may include plating a laser material, such as copper, to substrate 512. Plating the etch material and/or the laser material may be performed with or without solder. In addition to forming material 516, various bumps 522 may be formed at stage 520. Bumps 522 may be copper and/or solder plating materials that may be used to attach dies as disclosed herein.

One or more dies 524 may be attached and a mold 526 formed around dies 524 (528). Mold 526 may be ground as needed to be even with a top surface of dies 524 after an underfill process is used to form mold 526. For example, an underfilling process may be used to surround a portion of die 524 and mold 526 may contact substrate 512 and dies 524 as disclosed herein. Once mold 526 cures, a grinding process may be used to remove and flash or other portions of mold 526 as needed.

After attaching dies 524, a second carrier 530 may be attached to dies 524 (532A and 532B). After attaching second carrier 530, carrier 506 may be removed and a cavity 534 may be formed in substrate 512. For example, cavity 534 may be formed using a laser drilling process. During the laser drilling process, material 504 may limit the depth of cavity 534 by reflecting, absorbing, or a combination there the laser used to form cavity 534 as disclosed herein. Forming cavity 534 may also include etching or otherwise forming holes within material 506 to allow for an electrical connection between pillars 510 and a bridge 536 as disclosed herein.

Stage 532A shows material 504 being drilled and/or etched to form vias that allow for dies 524 to be connected to bridge 536, such as shown above with respect to FIGS. 2A and 2B. As such, in stage 532A, one or more portions of material 504 may remain in place after completion of process flow 500. Stage 532B shows process material 504 being completely removed by etching, drilling, etc. as shown above with respect to FIGS. 3A-3D.

Once cavity 534 is formed a bridge 536 may be installed in cavity 534 (538). Installing of bridge 536 may include electrically connecting bridge 536 to dies 524 via bumps as disclosed herein. After installing bridge 536, solder bumps 540 may be applied and second carrier 530 may be removed.

While process flows 400 and 500 have been described in a specific order, other process flows and sub process flows are contemplated and consistent with embodiments disclosed herein. For instance, instead of using a second carrier to ensure planarity for the bridge/ODI die attachment to the backside process flows could utilize a cold spray process prior to removal of the first carrier to simultaneously enable a stiff and flat panel or wafer, depending on if the process flow utilized is a panel or wafer-level process flow. In addition, an integrated heat spreader for increased thermal performance may be applied and used as a carrier thus minimizing or eliminating the need for a carrier. Another process variation may include instead of having the fine pitch ODI/bridge die hybrid bonded to a top-die-complex, solder attach may be used. For example, when the interconnect bump pitch is greater than 15 μm, solder attach may be used to connect the ODI/Bridge die to the top dies. Still consistent with embodiment disclosed herein, openings for the ODI/bridge dies may be formed on the first carrier and plated pillars used.

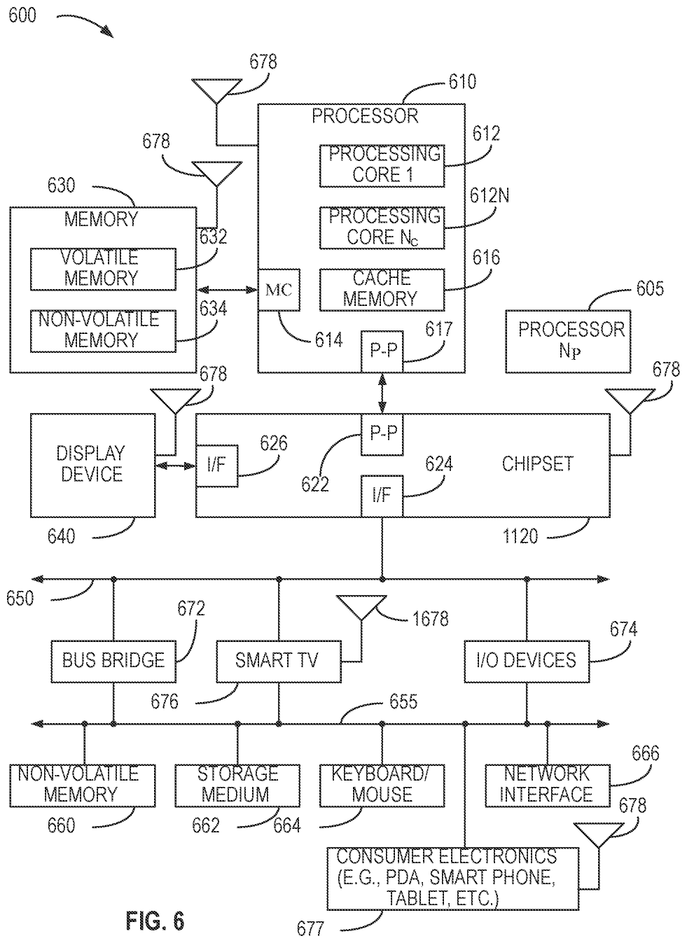

FIG. 6 illustrates a system level diagram, according to one embodiment of the invention. For instance, FIG. 6 depicts an example of an electronic device (e.g., system) including the microelectronics package 100 as described herein. FIG. 6 is included to show an example of a higher level device application for the present invention. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 is a system on a chip (SOC) system.

In one embodiment, processor 610 has one or more processing cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, the wireless antenna interface 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the invention, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices 672, 676, 674, 660, 662, 664, 666, 677, etc. Chipset 620 may also be coupled to a wireless antenna 678 to communicate with any device configured to transmit and/or receive wireless signals.

Chipset 620 connects to display device 640 via interface 626. Display 640 may be, for example, a liquid crystal display (LCD), a plasma display, cathode ray tube (CRT) display, or any other form of visual display device. In some embodiments of the invention, processor 610 and chipset 620 are merged into a single SOC. In addition, chipset 620 connects to one or more buses 650 and 655 that interconnect various elements 674, 660, 662, 664, and 666. Buses 650 and 655 may be interconnected together via a bus bridge 672. In one embodiment, chipset 620 couples with a non-volatile memory 660, a mass storage device(s) 662, a keyboard/mouse 664, and a network interface 666 via interface 624 and/or 604, smart TV 676, consumer electronics 677, etc.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

### Additional Notes

The following, non-limiting examples, detail certain aspects of the present subject matter to solve the challenges and provide the benefits discussed herein, among others.

Example 1 is a microelectronics package comprising: a substrate defining a cavity; a first die connected to the substrate and a first bump; a second die connected to the substrate and a second bump; a material attached to the substrate and located beneath adjacent edges of the first die and the second die, the material comprising an etch stopping material, copper, titanium, or an alloy of copper and titanium, the material further comprising: a first portion of the material located proximate the first bump, and a second portion of the material located proximate the second bump.

In Example 2, the subject matter of Example 1 optionally includes wherein the etch stopping material comprises oxygen or nitrogen.

In Example 3, the subject matter of any one or more of Examples 1-2 optionally include wherein the material comprises a laser stopping material.

In Example 4, the subject matter of any one or more of Examples 1-3 optionally include a bridge located in the cavity and a connection passing through the material to connect the first bump of the first die and the second bump of the second die.

In Example 5, the subject matter of any one or more of Examples 1-4 optionally include a third die connected to the substrate, the third die comprising a third bump; and a second material attached to the substrate, a first portion of the second material located proximate the third bump and a second portion of the second material located proximate the first bump or the second bump.

In Example 6, the subject matter of Example 5 optionally includes wherein the second material comprises a copper plate, a titanium plate, or an alloy of copper and titanium.

In Example 7, the subject matter of any one or more of Examples 1-6 optionally include a third die connected to the substrate, the third die comprising a third bump, a third portion of the material located proximate at least one of the first bump and the second bump.

Example 8 is a microelectronics package comprising: a substrate defining a cavity having a boundary; a first die connected to the substrate, the first die comprising a first bump; a second die connected to the substrate, the second die comprising a second bump; a bridge located in the cavity and connected to the first bump, and the second bump; a material attached to the substrate, wherein a portion of a surface of the material has a projection that defines the boundary of the cavity.

In Example 9, the subject matter of Example 8 optionally includes wherein the material comprises an etch stopping material.

In Example 10, the subject matter of any one or more of Examples 8-9 optionally include wherein the material comprises a laser stopping material.

In Example 11, the subject matter of any one or more of Examples 8-10 optionally include wherein the material comprises oxygen, nitrogen, a copper plate, a titanium plate, or an alloy of copper and titanium.

In Example 12, the subject matter of any one or more of Examples 8-11 optionally include wherein the substrate defines a second cavity, the microelectronics package further comprising: a third die connected to the substrate, the third die comprising a third bump; a second bridge located in the second cavity and connected to the third bump and at least one of the first bump and the second bump; and a second material attached to the substrate, a second portion of the surface of the second material has a projection defining a boundary of the second cavity.

In Example 13, the subject matter of any one or more of Examples 8-12 optionally include a third die connected to the substrate, the third die comprising a third bump, a third portion of the material located proximate at least one of the third bump.

Example 14 is a method of constructing a microelectronics package, the method comprising: forming a substrate on a carrier; attaching a material to the substrate; attaching a first die to the substrate, the first die having a first bump located proximate the material; attaching a second die to the substrate, the second die having a second bump located proximate the material; and forming a cavity in the substrate sized to receive a bridge, the cavity extending from a first surface of the substrate to the material.

In Example 15, the subject matter of Example 14 optionally includes wherein attaching the material to the substrate comprises plating an etch stopping material to the substrate without solder.

In Example 16, the subject matter of any one or more of Examples 14-15 optionally include wherein attaching the material to the substrate comprises plating a laser stopping material to the substrate without solder.

In Example 17, the subject matter of any one or more of Examples 14-16 optionally include wherein forming the cavity comprises laser drilling the substrate, the material defining a maximum drilling depth.

In Example 18, the subject matter of any one or more of Examples 14-17 optionally include wherein forming the cavity comprises etching the substrate, the material defining a maximum etch depth.

In Example 19, the subject matter of any one or more of Examples 14-18 optionally include installing a bridge in the cavity formed in the substrate, the bridge electrically coupling the first bump and the second bump.

In Example 20, the subject matter of any one or more of Examples 14-19 optionally include underfilling a mold around a portion of the first die and the second die, the mold contacting the substrate, the first die, and the second die.

In Example 21, the microelectronics packages, systems, apparatuses, or method of any one or any combination of Examples 1-20 can optionally be configured such that all elements or options recited are available to use or select from.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A microelectronics package comprising:
a substrate defining a cavity;
a first die connected to the substrate and a first bump;
a second die connected to the substrate and a second bump;
a material attached to the substrate and located beneath adjacent edges of the first die and the second die, the material comprising an etch stopping material, copper, titanium, or an alloy of copper and titanium, the material further comprising:
a first portion of the material located proximate the first bump, and
a second portion of the material located proximate the second bump.

2. The microelectronics package of claim 1, wherein the etch stopping material comprises oxygen or nitrogen.

3. The microelectronics package of claim 1, wherein the material comprises a laser stopping material.

4. The microelectronics package of claim 1, further comprising a bridge located in the cavity and a connection passing through the material to connect the first bump of the first die and the second bump of the second die.

5. The microelectronics package of claim 1, further comprising:
a third die connected to the substrate, the third die comprising a third bump; and
a second material attached to the substrate, a first portion of the second material located proximate the third bump and a second portion of the second material located proximate the first bump or the second bump.

6. The microelectronics package of claim 5, wherein the second material comprises a copper plate, a titanium plate, or an alloy of copper and titanium.

7. The microelectronics package of claim 1, further comprising a third die connected to the substrate, the third die comprising a third bump, a third portion of the material located proximate at least one of the first bump and the second bump.

8. A microelectronics package comprising:
a substrate defining a cavity having a boundary;
a first die connected to the substrate, the first die comprising a first bump;
a second die connected to the substrate, the second die comprising a second bump;
a bridge located in the cavity and connected to the first bump, and the second bump;
a material attached to the substrate,
wherein a portion of a surface of the material has a projection that defines the boundary of the cavity.

9. The microelectronics package of claim 8, wherein the material comprises an etch stopping material.

10. The microelectronics package of claim 8, wherein the material comprises a laser stopping material.

11. The microelectronics package of claim 8, wherein the material comprises oxygen, nitrogen, a copper plate, a titanium plate, or an alloy of copper and titanium.

12. The microelectronics package of claim 8, wherein the substrate defines a second cavity, the microelectronics package further comprising:
a third die connected to the substrate, the third die comprising a third bump;
a second bridge located in the second cavity and connected to the third bump and at least one of the first bump and the second bump; and
a second material attached to the substrate, a second portion of the surface of the second material has a projection defining a boundary of the second cavity.

13. The microelectronics package of claim 8, further comprising a third die connected to the substrate, the third die comprising a third bump, a third portion of the material located proximate at least one of the third bump.

14. A method of constructing a microelectronics package, the method comprising:
forming a substrate on a carrier;
attaching a material to the substrate;
attaching a first die to the substrate, the first die having a first bump located proximate the material;
attaching a second die to the substrate, the second die having a second bump located proximate the material; and
forming a cavity in the substrate sized to receive a bridge, the cavity extending from a first surface of the substrate to the material.

15. The method of claim 14, wherein attaching the material to the substrate comprises plating an etch stopping material to the substrate without solder.

16. The method of claim 14, wherein attaching the material to the substrate comprises plating a laser stopping material to the substrate without solder.

17. The method of claim 14, wherein forming the cavity comprises laser drilling the substrate, the material defining a maximum drilling depth.

18. The method of claim 14, wherein forming the cavity comprises etching the substrate, the material defining a maximum etch depth.

19. The method of claim 14, further comprising installing a bridge in the cavity formed in the substrate, the bridge electrically coupling the first bump and the second bump.

20. The method of claim 14, further comprising underfilling a mold around a portion of the first die and the second die, the mold contacting the substrate, the first die, and the second die.
